(19) United States
(12) Patent Application Publication
(10) Pub. No.: US 2005/0125763 A1
(43) Pub. Date: Jun. 9, 2005

(54) System and method for the online design of a reticle field layout

(75) Inventors: Ko-Feng Lin, Kaohsiung (TW); Yi-Hsu Chen, Hsinchu (TW); Lee-Chih Yeh, Keelung (TW); Chun-Jen Chen, Kaohsiung (TW); Ta-Chin Chin, Taipei City (TW)

Correspondence Address: HAYNES AND BOONE, LLP, 901 MAIN STREET, SUITE 3100, DALLAS, TX, 75202, US

(73) Assignee: Taiwan Semiconductor Manufacturing Company, Ltd., Hsin-Chu (TW)

(21) Appl. No.: 10/880,903

(22) Filed: Jun. 30, 2004

Related U.S. Application Data
(60) Provisional application No. 60/484,104, filed on Jun. 30, 2003.

(51) Int. Cl. G06F 17/50; G21K 5/00; G03F 9/00

(52) U.S. Cl. 716/21; 430/5; 378/35

(57) ABSTRACT

Provided are a system and method for creating a reticle field layout (RFL). In one example, the method includes receiving information for a RFL design by a computer system directly from a user via a computer interface. The RFL design is automatically verified using predefined specification and design rules accessible to the computer system. The RFL design may be modified by adding additional features before being finalized.

This application claims priority from U.S. Provisional Patent Application Ser. No. 60/484,104, filed on Jun. 30, 2003, and which is hereby incorporated by reference in its entirety. The present disclosure relates generally to the field of semiconductor manufacturing and, more particularly, to a system and method for reticle field layout design.

### BACKGROUND

The semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing have been needed.

Furthermore, as the IC industry has matured, the various operations needed to produce an IC may be performed at different locations by a single company or by different companies that specialize in a particular area. This further increases the complexity of producing ICs, as companies and their customers may be separated not only geographically, but also by time zones, making effective communication more difficult. For example, a first company (e.g., an IC design house) may design a new IC, a second company (e.g., an IC foundry) may provide the processing facilities used to fabricate the design, and a third company may assemble and test the fabricated IC. A fourth company may handle the overall manufacturing of the IC, including coordination of the design, processing, assembly, and testing operations.

Whether in the context of a single facility or multiple facilities, communication issues may present problems in a number of areas, such as in the fabrication of IC's designed by a customer. For example, in IC manufacturing processes that use a photomask (mask), the mask contains one or more circuit patterns that are projected onto a wafer. The patterns may be laid out on the mask using a reticle field layout (RFL) process. The design of the RFL generally involves both the customer ordering the IC and engineers from a manufacturing facility. However, as there is currently no standardized framework within which the customer may submit an RFL design, the customer may provide their RFL design to a manufacturing facility using a number of different formats. This introduces additional complexity into the design process, as engineers from the manufacturing facility may need to enter the data provided by the customer and communicate with the customer regarding aspects of the RFL that are unclear or incorrect.

Accordingly, what is needed is a system and method for improving RFL design capabilities and communicating the RFL design to a manufacturing facility. For example, it is desired to provide online communication, a standard framework and format, and a set of built-in specification and design rules.

### BRIEF DESCRIPTION OF THE DRAWINGS

FIG. 1 is a flowchart of an exemplary method for designing a reticle field layout (RFL).

FIG. 2 is a block diagram of one embodiment of a virtual fabrication (fab) system within which the method 100 of FIG. 1 may be performed.

FIG. 3 is a block diagram illustrating one possible implementation of the virtual fab of FIG. 2.

FIG. 4 is a block diagram of an exemplary computer that may be used within the virtual fab of FIGS. 2 or 3.

FIG. 5 is a block diagram of an exemplary RFL design system that may be used within the virtual fab of FIGS. 2 or 3.

FIG. 6 is an exemplary interface that enables a user to interact with the RFL design system of FIG. 5.

FIG. 7 is a flowchart of another exemplary method for designing a RFL.

FIGS. 8A and 8B illustrate exemplary RFL designs that may be created using the method of FIG. 7.

FIGS. 9A-9C illustrate exemplary RFL designs that may be created using the method of FIG. 7.

### DETAILED DESCRIPTION

The present disclosure relates generally to the field of semiconductor manufacturing and, more particularly, to a system and method for reticle field layout (RFL) design.

It is understood, however, that the following disclosure provides many different embodiments, or examples, for implementing different features of the invention. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

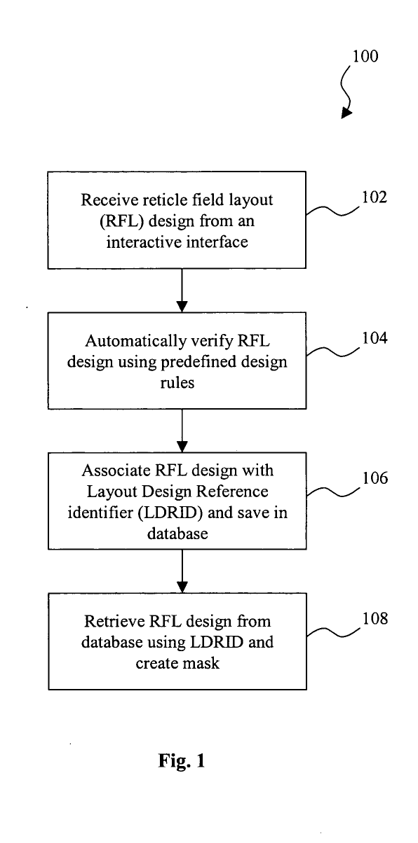

Referring now to FIG. 1, in one embodiment, a method 100 enables the creation, storage, and validation of a reticle field layout (RFL) design for an integrated circuit (IC). The RFL defines a mask that is used during photolithography to place circuits onto the IC. In the present example, the RFL design is created by a user who may enter RFL design information via an interactive interface, such as may be accessed using a web browser. In step 102, the RFL design information is received from the interactive interface by a manufacturing facility, such as a design or fabrication facility. As will be described later in greater detail, the RFL design information may include the selection of IC manufacturing technologies that are associated with the mask, including information like the use of a 300 mm wafer and 0.13 micron technology.

In step 104, the received RFL design is automatically verified using a set of predefined design rules to ensure the integrity of the design. In step 106, the RFL design information is associated with a Layout Design Reference identifier (LDRID) that is used to associate the RFL design with other information relevant to the order, and is stored in a database that is accessible to the manufacturing facility. This enables the manufacturing facility to locate the RFL design and use it during the manufacturing process of the proper order. In step 108, the RFL design is retrieved from the database and used to create a mask.

The method 100 may be used to extend customer service so that a customer can independently (e.g., without engineering support from the manufacturing facility) design a RFL using built-in design specifications and rules. The method 100 may also reduce photomask production cycle time by minimizing or eliminating the time and effort needed to communicate and confirm a design.

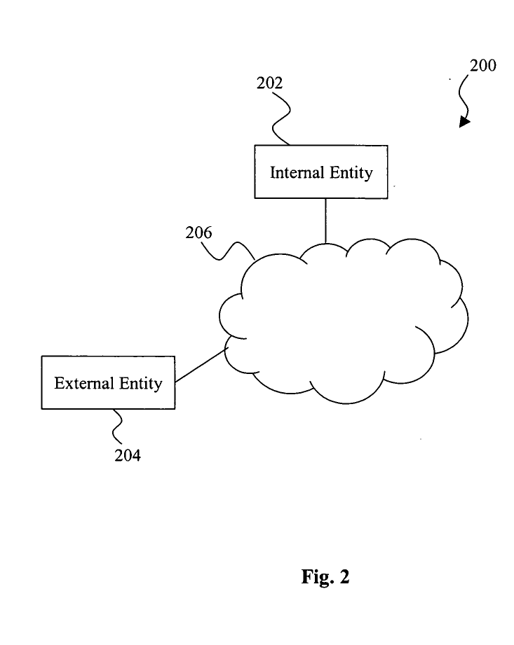

Referring now to FIG. 2, a virtual IC fabrication system (a “virtual fab”) 200 is one embodiment of a system that can be used to implement the method 100 of FIG. 1. The virtual fab includes a plurality of entities, represented by one or more internal entities 202 and one or more external entities 204 that are connected by a communications network 206. The network 206 may be a single network or may be a variety of different networks, such as an intranet and the Internet, and may include both wireline and wireless communication channels.

In the present example, the internal entities 202 represents those entities that are directly responsible for producing the end product, such as a wafer or individually tested IC devices. Examples of internal entities 202 include an engineer, customer service personnel, an automated system process, a design or fabrication facility and fab-related facilities such as raw-materials, shipping, assembly or test. Examples of external entities 204 include a customer, a design provider; and other facilities that are not directly associated or under the control of the fab. In addition, additional fabs and/or virtual fabs can be included with the internal or external entities. Each entity may interact with other entities and may provide services to and/or receive services from the other entities.

It is understood that the entities 202-204 may be concentrated at a single location or may be distributed, and that some entities may be incorporated into other entities. In addition, each entity 202, 204 may be associated with system identification information that allows access to information within the system to be controlled based upon authority levels associated with each entities identification information.

The virtual fab 200 enables interaction among the entities 202-204 for purposes related to IC manufacturing, as well as the provision of services. In the present example, IC manufacturing can include one or more of the following steps:
receiving or modifying a customer's IC order of price, delivery, and/or quantity;
receiving or modifying an IC design;
receiving or modifying a process flow;
receiving or modifying a circuit design;
receiving or modifying a mask change;
receiving or modifying testing parameters;
receiving or modifying assembly parameters; and
receiving or modifying shipping of the ICs.

One or more of the services provided by the virtual fab 200 may enable collaboration and information access in such areas as design, engineering, and logistics. For example, in the design area, the customer 204 may be given access to information and tools related to the design of their product via the fab 202. The tools may enable the customer 204 to perform yield enhancement analyses, view layout information, and obtain similar information. In the engineering area, the engineer 202 may collaborate with other engineers 202 using fabrication information regarding pilot yield runs, risk analysis, quality, and reliability. The logistics area may provide the customer 204 with fabrication status, testing results, order handling, and shipping dates. It is understood that these areas are exemplary, and that more or less information may be made available via the virtual fab 200 as desired.

Another service provided by the virtual fab 200 may integrate systems between facilities, such as between a facility 204 and the fab facility 202. Such integration enables facilities to coordinate their activities. For example, integrating the design facility 204 and the fab facility 202 may enable design information to be incorporated more efficiently into the fabrication process, and may enable data from the fabrication process to be returned to the design facility 204 for evaluation and incorporation into later versions of an IC.

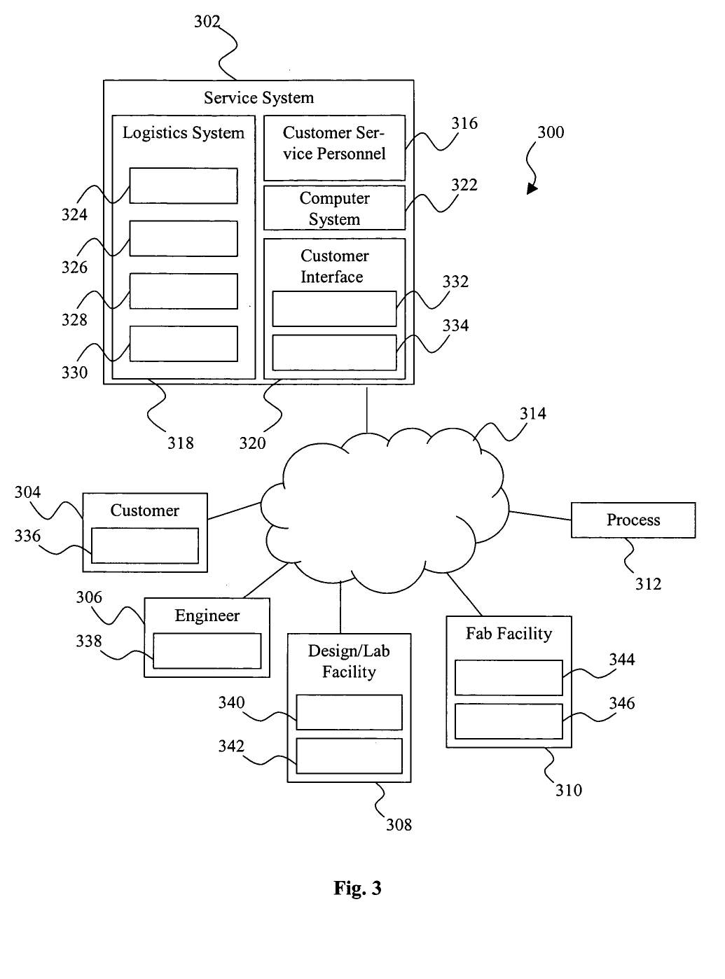

Referring now to FIG. 3, a virtual fab 300 illustrates a more detailed example of the virtual fab 200 of FIG. 2. It is understood, however, that the details mentioned and described in FIG. 3 are provided for the sake of example, and that other examples can also be used.

The virtual fab 300 includes a plurality of entities 302, 304, 306, 308, 310, and 312 that are connected by a communications network 314. In the present example, the entity 302 represents a service system, the entity 304 represents a customer, the entity 306 represents an engineer, the entity 308 represents a design/lab facility for IC design and testing, the entity 310 represents a fab facility, and the entity 312 represents a process (e.g., an automated fabrication process). Each entity may interact with other entities and may provide services to and/or receive services from the other entities.

The service system 302 provides an interface between the customer and the IC manufacturing operations. For example, the service system 302 may include customer service personnel 316, a logistics system 318 for order handling and tracking, and a customer interface 320 for enabling a customer to directly access various aspects of an order.

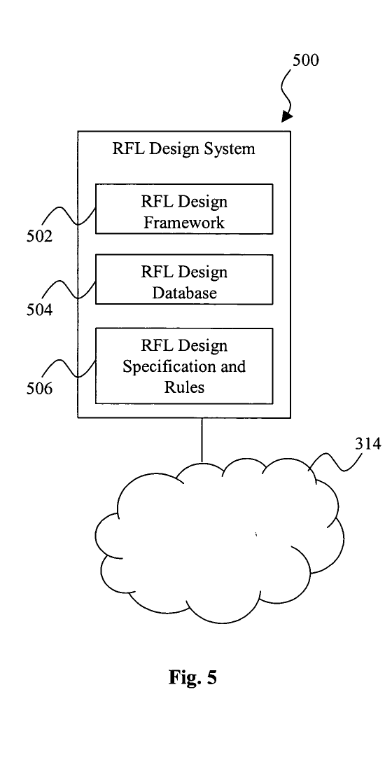

The logistics system 318 may include a RFL design system 324, a product data management system 326, a lot control system 328, and a manufacturing execution system (MES) 330. As will be discussed in greater detail with reference to FIG. 5, the RFL design system 324 may contain hardware and software for creating an RFL design. The product data management system 326 may manage product data and maintain a product database (not shown). The product database could include product categories (e.g., part, part numbers, and associated information), as well as a set of process stages that are associated with each category of products. The lot control system 328 may convert a process stage to its corresponding process steps.

The MES 330 may be an integrated computer system representing the methods and tools used to accomplish production. In the present example, the primary functions of the MES 330 may include collecting data in real time, organizing and storing the data in a centralized database, work order management, workstation management, process management, inventory tracking, and document control. The MES 330 may be connected to other systems both within the service system 302 and outside of the service system 302. Examples of the MES 330 include Promis, Workstream, Poseidon, and Mirl-MES. Each MES may have a different application area. For example, Mirl-MES may be used in applications involving packaging, liquid crystal displays (LCDs), and printed circuit boards (PCBs), while Promis, Workstream, and Poseidon may be used for IC fabrication and thin film transistor LCD (TFT-LCD) applications. The MES 330 may include such information as a process step sequence for each product.

The customer interface 320 may include an online system 332 and an order management system 334. The online system 332 may function as an interface to communicate with the customer 304, other systems within the service system 302, supporting databases (not shown), and other entities 306-312. The order management system 334 may manage client orders and may be associated with a supporting database (not shown) to maintain client information and associated order information.

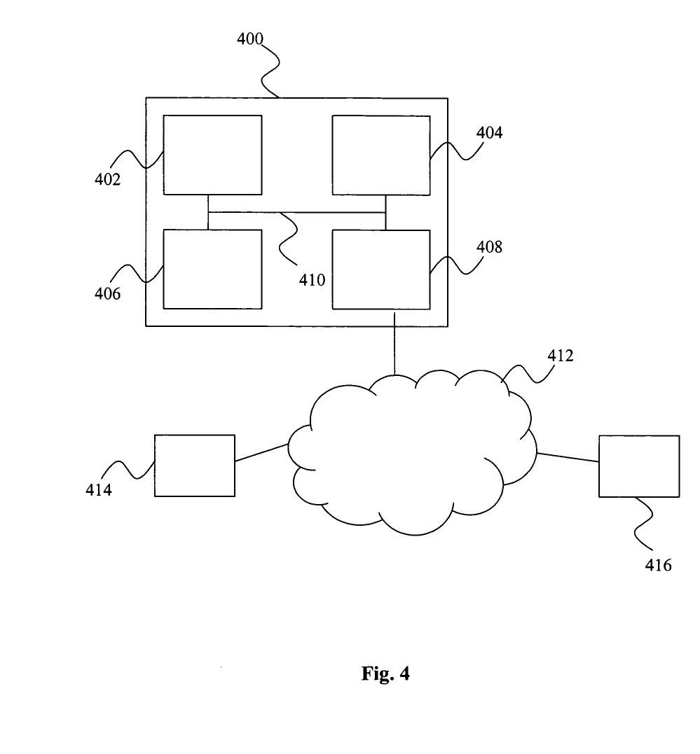

Portions of the service system 302, such as the customer interface 320, may be associated with a computer system 322 or may have their own computer systems. In some embodiments, the computer system 322 may include multiple computers (FIG. 4), some of which may operate as servers to provide services to the customer 304 or other entities. The service system 302 may also provide such services as identification validation and access control, both to prevent unauthorized users from accessing data and to ensure that an authorized customer can access only their own data.

The customer 304 may obtain information about the manufacturing of its ICs via the virtual fab 300 using a computer system 336. In the present example, the customer 304 may access the various entities 302, 306-312 of the virtual fab 300 through the customer interface 320 provided by the service system 302. However, in some situations, it may be desirable to enable the customer 304 to access other entities without going through the customer interface 320. For example, the customer 304 may directly access the fab facility 310 to obtain fabrication related data.

The engineer 306 may collaborate in the IC manufacturing process with other entities of the virtual fab 300 using a computer system 338. The virtual fab 300 enables the engineer 306 to collaborate with other engineers and the design/lab facility 308 in IC design and testing, to monitor fabrication processes at the fab facility 310, and to obtain information regarding test runs, yields, etc. In some embodiments, the engineer 306 may communicate directly with the customer 304 via the virtual fab 300 to address design issues and other concerns.

The design/lab facility 308 provides IC design and testing services that may be accessed by other entities via the virtual fab 300. The design/lab facility 308 may include a computer system 340 and various IC design and testing tools 342. The IC design and testing tools 342 may include both software and hardware.

The fab facility 310 enables the fabrication of ICs. Control of various aspects of the fabrication process, as well as data collected during the fabrication process, may be accessed via the virtual fab 300. The fab facility 310 may include a computer system 344 and various fabrication hardware and software tools and equipment 346. For example, the fab facility 310 may include an ion implantation tool, a chemical vapor deposition tool, a thermal oxidation tool, a sputtering tool, and various optical imaging systems, as well as the software needed to control these components.

The process 312 may represent any process or operation that occurs within the virtual fab 300. For example, the process 312 may be an order process that receives an IC order from the customer 304 via the service system 302, a fabrication process that runs within the fab facility 310, a design process executed by the engineer 306 using the design/lab facility 308, or a communications protocol that facilities communications between the various entities 302-312.

It is understood that the entities 302-312 of the virtual fab 300, as well as their described interconnections, are for purposes of illustration only. For example, it is envisioned that more or fewer entities, both internal and external, may exist within the virtual fab 300, and that some entities may be incorporated into other entities or distributed. For example, the service system 302 may be distributed among the various entities 306-310.

Referring now to FIG. 4, an exemplary computer 400, such as may be used within the virtual fab 200 of FIG. 2 or virtual fab 300 of FIG. 3, is illustrated. The computer 400 may include a central processing unit (CPU) 402, a memory unit 404, an input/output (I/O) device 406, and a network interface 408. The network interface may be, for example, one or more network interface cards (NICs). The components 402, 404, 406, and 408 are interconnected by a bus system 410. It is understood that the computer may be differently configured and that each of the listed components may actually represent several different components. For example, the CPU 402 may actually represent a multi-processor or a distributed processing system; the memory unit 404 may include different levels of cache memory, main memory, hard disks, and remote storage locations; and the 1/0 device 406 may include monitors, keyboards, and the like.

The computer 400 may be connected to a network 412, which may be connected to the networks 206 (FIG. 2) or 314 (FIG. 3). The network 412 may be, for example, a complete network or a subnet of a local area network, a company wide intranet, and/or the Internet. The computer 400 may be identified on the network 412 by an address or a combination of addresses, such as a media control access (MAC) address associated with the network interface 408 and an internet protocol (IP) address. Because the computer 400 may be connected to the network 412, certain components may, at times, be shared with other devices 414, 416. Therefore, a wide range of flexibility is anticipated in the configuration of the computer. Furthermore, it is understood that, in some implementations, the computer 400 may act as a server to other devices 414, 416. The devices 414, 416 may be computers, personal data assistants, wired or cellular telephones, or any other device able to communicate with the computer 400.

Referring now to FIG. 5, in another embodiment, the RFL design system 324 is illustrated in greater detail. It is understood that, although the RFL design system 324 is shown as a component of the logistics system 318 in FIG. 3, the RFL design system 324 may actually be a separate entity or may be formed using existing entities, such as the design/lab facility 308 and the online system 332 of the customer interface 320. In the present example, the RFL design system 324 is connected to the network 314, and includes an RFL design framework 502, an RFL design database 504, and a set of RFL design specification and rules 506.

The RFL design framework 502 may include an online accessible interface (which may be the online system 332), a standard design format and template, and data processing software and hardware. The RFL design database 504 may include an RFL database to store RFL design data received from the RFL design framework 502 and which is retrievable by an LDRID, and a customer database to store customer data and photomask order information. The RFL design specification and rules 506 may include multiple sets of specifications and associated rules for IC manufacturing technologies. For example, the RFL design specification and rules 506 may include rules needed to produce an IC using a 300 mm wafer, a 0.13 micron feature size, and BiCMOS technology. The RFL design system 324, either separately or in conjunction with the service system 302 in the virtual fab 300 (FIG. 3), may provide an RFL design platform with online communication, a standard format, and built-in specifications and design rules to both customers and engineers.

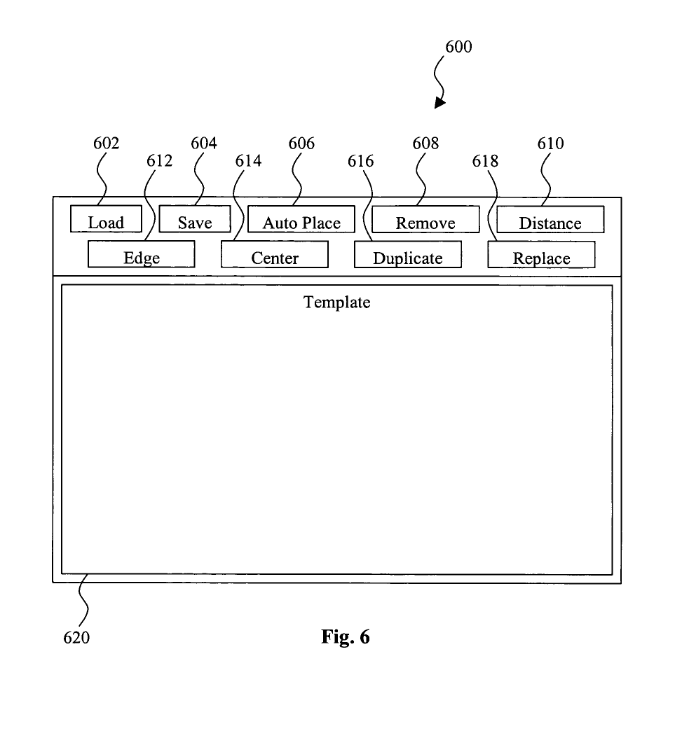

Referring now to FIG. 6, an interface 600 illustrates one means by which a customer may interact with the online accessible interface of the RFL design system 324 of FIG. 5. It is understood that a variety of interfaces may be presented to the customer, such as a login interface and a help interface that provides the customer with instructions on how to accomplish various tasks. After the customer logins to the RFL design system, the interface 600 presents the customer with several options. In the present example, the interface 600 includes a Load button 602, a Save button 604, an Auto place button 606, a Remove button 608, a Distance button 610, an Edge button 612, a Center button 614, a Duplicate button 616, and a Replace button 618. The interface 600 may also include a template 620 that provides the customer with a basic RFL design layout. The template 620 may be updated by the RFL design specification and rules 506 during the design process to ensure that the RFL design is correct. Alternatively, the RFL design specification and rules 506 may be applied to the template 620 after the design is completed.

The Load and Save buttons 602, 604 provide the customer with the option to either load a draft RFL design from or save a draft RFL design to the RFL design database. The Auto place button 606 may place a design component in a recommended area (e.g., using the RFL design specification and rules 506). The Remove button 608 enables the customer to remove a component from the RFL design, while the Distance button 610 enables the customer to specify a distance between components or from the edge. For example, activating the Distance button 612 may bring up a user selectable menu or may present a box into which the customer can enter a desired distance.

The Edge button 612 may be used to specify a distance around the edge of the design, while the Center button 614 may enable the customer to center a component, either within the layout or relative to another component. The Duplicate button 616 may enable the customer to duplicate an existing component or an existing parameter (e.g., orientation, alignment, etc.). The Replace button 618 may enable a selected component to be replaced by another component. It is understood that the buttons and functions are illustrative, and that many other buttons and functions may be provided. For example, a context sensitive menu may be activated by clicking on a mouse button (not shown) or by using a keyboard (not shown). Accordingly, the interface 600 may be altered as desired to extend its functionality and to maximize customer support during the RFL design process.

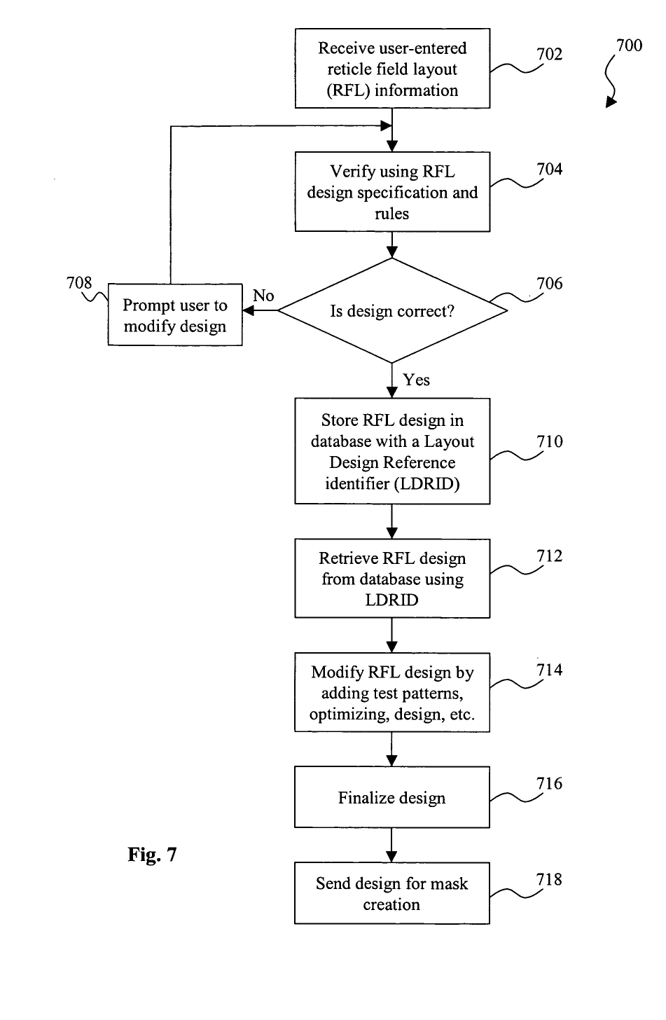

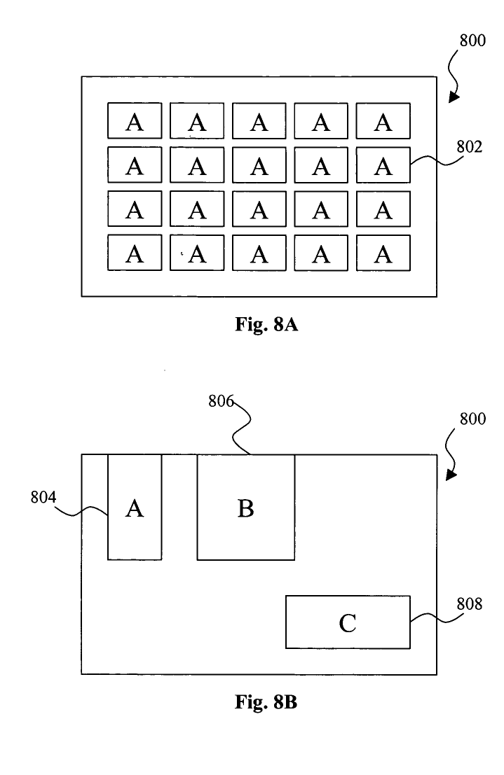

Referring now to FIG. 7, and with additional reference to FIGS. 8A and 8B, in still another embodiment, a method 700 may be used in conjunction with the interface 600 of FIG. 6 to provide RFL design capabilities within a virtual fab. In step 702, RFL information is received via the interface 600. Referring also to FIGS. 8A and 8B, an exemplary reticle field layout 800 is illustrated. The RFL information received in step 702 details one or more patterns that are to be transferred to a photomask for use in photolithography. As described previously, in IC manufacturing, a photomask is used to pattern a wafer for one or more electric circuits. The mask contains a pattern (defined by the RFL process) which details the circuits. The pattern, which may occupy a relatively small area on the mask, is projected onto the wafer during the fabrication process of an IC. If a customer wants to produce only one type of IC, then the same pattern may be repeated on the mask to form a matrix (e.g., five rows by four columns), such as is illustrated in FIG. 8A. In FIG. 8A, the symbol ‘A’ represents a single type of pattern 802. Because the RFL defines how the patterns are placed on a mask, an RFL having a matrix of one pattern is relatively simple.

However, the customer may want to produce more than one type of IC on a wafer (referred to as a “combo job”). This means that multiple patterns need to be formed on a single mask, with each pattern having its own structure and dimensions. Generally, a mask may have multiple patterns, although the number of patterns may depend on such issues as wafer surface capacity and design specifications/rules. FIG. 8B illustrates an example of a RFL with a combo job, where the symbols ‘A,’ ‘B,’ and C’ represent different patterns 804, 806, and 808, respectively.

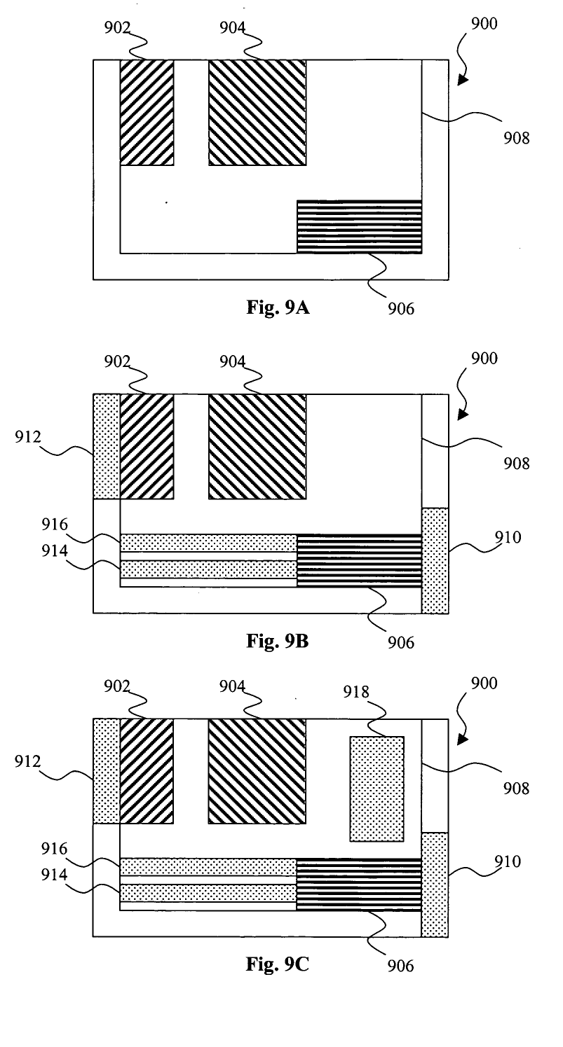

Referring now to FIG. 9A and with continued reference to FIG. 7, a RFL design 900 mirrors the RFL of FIG. 8B. The RFL design 900 in FIG. 9A contains patterns 902, 904, and 906, which are different patterns. The line 908 is a scribe line, which is a space on a wafer between die that aids in the separation of the die. In the present example, the information received in step 702 is represented in FIG. 9A and is the first draft of a RFL that was completed by the customer. In step 704, the RFL design 900 is verified using the RFL design specification and rules 506 of the design system 324 of FIG. 5. In step 706, a determination is made as to whether the design is correct in light of the RFL design specification and rules 506 applied in step 704. If the design is not correct, the user is prompted for corrections in step 708 and the method 700 returns to step 704 for verification. It is understood that other verification methods are possible, and that the design may be verified as each component is added by the customer or later in the design process. Because of this verification step, the RFL design 900 is known to be compatible with available manufacturing technology, and need not be confirmed by an engineer during manufacturing. If the design is correct, the method 700 continues to step 710, where the design is stored in a database with a LDRID. In step 712, the RFL design 900 may be retrieved from the database using the LDRID and, in step 714, various modifications may be made.

Referring now to FIG. 9B and with continued reference to FIG. 7, the RFL 900 illustrates modifications made during step 714. The RFL 900 of FIG. 9B includes additional portions 910, 912, 914, and 916. The additional portions may include test patterns, frame cells, and similar modifications. The test patterns may be electric circuits used by an IC fab (e.g., the fab facility 310 of FIG. 3) to optimize yields, provide process control feedback, and assure device quality. The frame cells may be structures used for photomask registration and alignment. Because the RFL design 900 is accessible via the RFL design system 324 (FIG. 5), engineers may make modifications directly to the RFL design 900 or may work with a copy. This prevents errors that may otherwise occur due to converting between file formats, entering customer information from paper, or using similar, non-standardized methods. Simulation tools may be used to optimize the layout of the patterns 902, 904, 906, and to add the test patterns and frame cells. The method 700 then continues to step 716, where the RFL design 900 is finalized.

Referring now to FIG. 9C and with continued reference to FIG. 7, the finalized RFL design 900 includes an additional portion 918, which may be a special test pattern or frame cell. The finalized RFL design 900 includes any special requests from the customer or/and engineers that may not be automatically processed by designing tools. For example, a certain test pattern may need to be placed vertically, or a special arrangement and design may be needed if the scribe line 908 is not able to take the test patterns and frame cells. The finalized RFL design 900 may then be sent for mask preparation. Alternatively, the finalized RFL design 900 may be stored in the database and retrieved again later using the LDRID.

The present disclosure has been described relative to a preferred embodiment. Improvements or modifications that become apparent to persons of ordinary skill in the art only after reading this disclosure are deemed within the spirit and scope of the application. It is understood that several modifications, changes and substitutions are intended in the foregoing disclosure and in some instances some features of the invention will be employed without a corresponding use of other features. Accordingly, it is appropriate that the appended claims be construed broadly and in a manner consistent with the scope of the invention.

1. A method for creating a reticle field layout (RFL) using a computer system, the method comprising:
receiving information for a RFL design by the computer system directly from a user via a computer interface;
automatically verifying the RFL design using a plurality of predefined specification and design rules accessible to the computer system;
modifying the RFL design by adding additional features; and
finalizing the RFL design.

2. The method of claim 1 further comprising
storing the verified RFL design in a database using an identifier associated with the RFL design; and
retrieving the stored RFL design from the database using the identifier prior to modifying the RFL design.

3. The method of claim 1 wherein adding additional features includes adding at least one of a test pattern or a frame cell.

4. The method of claim 1 further comprising creating a mask using the finalized RFL design.

5. The method of claim 1 further comprising:
automatically verifying the design to determine whether the design is correct; and
prompting the user to modify the design if the design is not correct.

6. The method of claim 5 further comprising providing a template to the user, wherein the template provides the user with a basic RFL design that can be edited by the user.

7. The method of claim 6 wherein the RFL design is automatically verified as the template is edited by the first user.

8. The method of claim 6 wherein the RFL design is automatically verified after the user is finished editing the template.

9. The method of claim 6 further comprising:
selecting, by the user, a desired integrated circuit manufacturing technology, wherein the plurality of predefined specification and design rules are each associated with at least one of a plurality of different manufacturing technologies; and
automatically selecting the template from a plurality of templates based on the desired manufacturing technology.

10. A system for creating a reticle field layout (RFL) using a computer system, the system comprising:
a first database containing a plurality of predefined specification and design rules;
a standard design format stored in the first database;
a computer interface accessible to the first database;
a processor accessible to the first database, format, and interface; and
a memory accessible to the processor, the memory containing instructions for execution by the processor, the instructions including:
instructions for receiving information for a RFL design directly from a first user via the interface;
instructions for incorporating the received information into the standard design format as the RFL design;
instructions for automatically verifying the received RFL design using the predefined specification and design rules;
instructions for enabling a second user to modify the verified RFL design; and
instructions for indicating that the RFL design is complete.

11. The system of claim 10 further comprising instructions for providing a template, wherein the template provides the first user with a basic RFL design that can be edited by the first user.

12. The system of claim 11 wherein the instructions for automatically verifying the received RFL design are applied as the template is edited by the first user.

13. The system of claim 11 wherein the instructions for automatically verifying the received RFL design are applied after the user is finished editing the template.

14. The system of claim 11 wherein the plurality of predefined specification and design rules contained in the first database are each associated with at least one of a plurality of different integrated circuit manufacturing technologies, and wherein the instructions further include:
instructions for selecting, by the first user, a desired manufacturing technology; and
instructions for automatically selecting the template from a plurality of templates based on the desired manufacturing technology.

15. The system of claim 10 further comprising a second database accessible to the processor, wherein the second database contains customer data and order information.

16. The system of claim 15 further comprising:
instructions for assigning an identifier to the RFL design;
instructions for storing the RFL design in the second database using the identifier; and
instructions for retrieving the stored RFL design from the second database.

17. The system of claim 16 further comprising instructions for ensuring that the RFL design has been verified prior to storing the RFL design in the second database.

18. The system of claim 10 wherein the first user is a customer.

19. A computer readable medium containing computer-executable instructions stored thereon, the instructions comprising:
instructions for receiving a reticle field layout (RFL) design from an interactive computer interface;
instructions for automatically verifying the RFL design using a plurality of predefined specification and design rules;
instructions for associating the RFL design with a layout design reference identifier;
instructions for storing and retrieving the RFL design using the identifier; and
instructions for using the RFL design to create a mask.

20. The computer readable medium of claim 19 wherein the instructions further comprise instructions for providing a template, wherein the template provides a user of the interactive computer interface with a basic RFL design that can be edited by the user.

21. The computer readable medium of claim 20 wherein the instructions further comprise:
instructions for enabling the user to select a desired integrated circuit manufacturing technology, wherein the plurality of predefined specification and design rules are each associated with at least one of a plurality of different manufacturing technologies; and
instructions for automatically selecting the template from a plurality of templates based on the desired manufacturing technology.

22. The computer readable medium of claim 19 wherein the instructions further comprise:
instructions for automatically verifying the design to determine whether the design is correct; and
instructions for prompting a user to modify the design if the design is not correct.
